(19) United States
(12) Patent Application Publication
(10) Pub. No.: US 2018/0090524 A1
(43) Pub. Date: Mar. 29, 2018

(54) IMAGE SENSOR PACKAGE AND METHOD OF PACKAGING THE SAME

(71) Applicant: China Water Level CSP Co., Ltd., Suzhou (CN)

(72) Inventor: Zhiqi Wang, Suzhou (CN)

(73) Assignee: China Water Level CSP Co., Ltd., Suzhou (CN)

(21) Appl. No.: 15/711,414

(22) Filed: Sep. 21, 2017

(30) Foreign Application Priority Data
Sep. 26, 2016 (CN) 201610846900.7
Sep. 26, 2016 (CN) 201621077065.7

(51) Int. Cl. H01L 27/146; H01L 23/31; H01L 23/48; H01L 21/56

(52) U.S. Cl. CPC H01L 27/146; H01L 23/31; H01L 23/48; H01L 2224/8592; H01L 2224/48091; H01L 2224/48465; H01L 21/56

(57) ABSTRACT

An image sensor package and a method of packaging an image sensor are provided. The package includes: an image sensor chip including a first surface and a second surface opposite to each other, where the first surface is provided with a photosensitive region; a transparent substrate including a first surface and a second surface opposite to each other, where the first surface of the transparent substrate covers the first surface of the image sensor chip; and a light absorption layer, where the light absorption layer covers sidewalls of the transparent substrate. By forming the light absorption layer on at least the sidewalls of the transparent substrate of the image sensor package, defects of the image sensor chip such as bad imaging and ghosting are eliminated, thereby improving an imaging quality of the image sensor chip.

### CROSS REFERENCE TO RELATED APPLICATION

The present application claims the priority to Chinese Patent Application No. 201610846900.7, titled “IMAGE SENSOR PACKAGE AND METHOD OF PACKAGING IMAGE SENSOR” and No. 201621077065.7, titled “IMAGE SENSOR PACKAGE”, filed on Sep. 26, 2016 with the State Intellectual Property Office of the PRC, both of which are incorporated herein by reference in their entireties.

### FIELD

The present disclosure relates to the technical field of semiconductors, and particularly to an image sensor chip packaging technology.

### BACKGROUND

With the development of light and shadow technology such as photography, an image sensor chip, as a functional chip being capable of converting received optical signals into electrical signals, is usually used in cameras of electronic products and is popular in the market.

Meanwhile, the image sensor chip packaging technology also makes substantial progress. Currently, the wafer level chip size packaging (WLCSP) technology is the mainstream image sensor chip packaging technology, in which a full wafer is packaged and tested, and then is cut to acquire individual finished chips. By using this kind of packaging technology, the packaged individual finished chip almost has the same size as an individual crystalline grain, which meets the market requirement for lighter, smaller, shorter, thinner and lower-priced microelectronic products. The wafer level chip size packaging technology is a hotspot in the current packaging field, and represents a development trend in the future.

The image sensor chip is provided with a photosensitive region on one surface thereof. Generally, a transparent substrate is covered on the surface provided with the photosensitive region of a wafer of the image sensor chip, in order to protect the photosensitive region from damage and pollution during packaging. The transparent substrate may be retained after the wafer level packaging and cutting is finished, to protect the image sensor chip permanently during the subsequent processes and applications.

The transparent substrate has transparency, to facilitate the absorption of light by the photosensitive region of the image sensor chip. However, the transparent substrate brings some bad consequences though it protects the image sensor chip. Commonly, optical reflection occurs at sidewalls of the transparent substrate when light enters the transparent substrate, resulting in bad imaging and ghosting. This kind of bad consequences become urgent technical problems to be solved by those skilled in the art.

Reference is made to FIG. 1, which is a schematic structural diagram of an image sensor package according to the conventional technology. The image sensor package includes: an image sensor chip 10 including a first surface and a second surface opposite to each other, where the first surface is provided with a photosensitive region 20 and contact pads 21 located at periphery of the photosensitive region 20; through holes located on the second surface of the image sensor chip 10 through which the contact pads 21 are exposed; an insulation layer 11 located on sidewalls of the through holes and the second surface of the image sensor chip 10; a metal wiring layer 12 located in the through holes and extending to the second surface of the image sensor chip 10, where the metal wiring layer 12 is electrically connected to the contact pads 21; a solder mask 13 covering the metal wiring layer 12 and the second surface of the image sensor chip 10, where the solder mask 13 has openings; solder bumps 14 located in the openings of the solder mask 13 and electrically connected to the metal wiring layer 12; a transparent substrate 30 covering the first surface of the image sensor chip 10; and a supporting structure 21 arranged on the transparent substrate 30 and located between the transparent substrate 30 and the image sensor chip 10, where an accommodating cavity is formed by surrounding by the supporting structure 21, the transparent substrate 30 and the image sensor chip 10, and the photosensitive region 20 is located in the accommodating cavity.

When the above image sensor chip is used, light I1 reaches the transparent substrate 30, and a part of the light I2 irradiates a sidewall 30s of the transparent substrate 30, and thus optical reflection occurs. If reflected light enters the photosensitive region 20, imaging of the image sensor chip will be interfered. Particularly, if an incident angle of the light I2 meets some specific conditions, for example, the transparent substrate 30 is glass and outside the glass is air, and if the incident angle of the light I2 is greater than a critical angle between the glass and the air, the light I2 will be totally reflected at the sidewall 30s of the transparent substrate 30. The totally reflected light I2 propagates in the transparent substrate 30 and is refracted to the photosensitive region 20, which will seriously interfere with the photosensitive region 20, thereby resulting in bad imaging or ghosting of the image sensor chip and reducing an imaging quality.

With the development of the technology, there are more and more image sensor chips integrated on a wafer. The size of an individual finished chip package is increasingly small, and the distance from the sidewall of the transparent substrate 30 to the edge of the photosensitive region 20 is increasingly short, and thus the interference phenomenon is more obvious.

### SUMMARY

An object of the present disclosure is to provide a new image sensor package and method of packaging an image sensor, so as to eliminate defects of an image sensor chip such as bad imaging and ghosting and improve an imaging quality of the image sensor chip.

An image sensor package is provided according to the present disclosure, which includes: an image sensor chip including a first surface and a second surface opposite to each other, where the first surface is provided with a photosensitive region; a transparent substrate including a first surface and a second surface opposite to each other, where the first surface of the transparent substrate covers the first surface of the image sensor chip; and a light absorption layer, where the light absorption layer covers sidewalls of the transparent substrate.

Preferably, a supporting structure may be arranged between the transparent substrate and the image sensor chip to form a gap between the transparent substrate and the image sensor chip; an accommodating cavity may be formed by surrounding by the supporting structure, the transparent substrate and the image sensor chip; the photosensitive region may be located in the accommodating cavity; and the light absorption layer may cover outer sidewalls of the supporting structure.

Preferably, the first surface of the image sensor chip may be provided with contact pads, the contact pads may be located at periphery of the photosensitive region; the second surface of the image sensor chip may be provided with through holes through which the contact pads are exposed; a metal wiring layer electrically connected to the contact pads may be arranged in the through holes, the metal wiring layer may extend to the second surface of the image sensor chip; solder bumps electrically connected to the metal wiring layer may be provided on the second surface of the image sensor chip; the light absorption layer may cover sidewalls and the second surface of the image sensor chip, and the solder bumps may be exposed through the light absorption layer.

Preferably, the light absorption layer may be made of vinyl.

A method of packaging an image sensor is further provided according to the present disclosure, which includes: providing a wafer including a first surface and a second surface opposite to each other, where the wafer is provided with multiple image sensor chips arranged in an array, each of the image sensor chips is provided with a photosensitive region, and the photosensitive region is located on the first surface; providing a transparent cover plate including a first surface and a second surface opposite to each other, where the transparent cover plate includes multiple transparent substrates, where each of the transparent substrates corresponds to one of the image sensor chips; laminating the wafer with the transparent cover plate, where the first surface of the transparent cover plate covers the first surface of the wafer; cutting a wafer level image sensor package into multiple packages by a cutting process, where each of the packages is provided with one of the image sensor chips and one of the transparent substrates; and forming a light absorption layer on sidewalls of the transparent substrate.

Preferably, the forming the light absorption layer may include: providing a substrate holder; fixing the multiple packages on the substrate holder, where the second surface of the transparent substrate is arranged on the substrate holder; and performing injection molding on the multiple packages by an injection molding process to form the light absorption layer.

Preferably, before the laminating the wafer with the transparent cover plate, the method may further include: forming a supporting structure on the first surface of the transparent cover plate; and forming multiple accommodating cavities by surrounding by the supporting structure, the transparent cover plate and the wafer, where each of the accommodating cavities corresponds to one of the image sensor chips, the photosensitive region is located in the accommodating cavity, and the light absorption layer covers outer sidewalls of the supporting structure.

Preferably, the first surface of the image sensor chip may be further provided with contact pads, and the contact pads may be located at periphery of the photosensitive region; the second surface of the image sensor chip may be provided with through holes through which the contact pads are exposed; the through holes may be provided with a metal wiring layer electrically connected to the contact pads, and the metal wiring layer may extend to the second surface of the image sensor chip; the second surface of the image sensor chip may be provided with solder bumps electrically connected to the metal wiring layer, the light absorption layer may cover sidewalls and the second surface of the image sensor chip, and the solder bumps may be exposed through the light absorption layer.

Preferably, the light absorption layer may be made of vinyl.

The beneficial effects of the present disclosure are as follows. By forming a light absorption layer on at least sidewalls of a transparent substrate of the image sensor package, defects of the image sensor chip such as bad imaging and ghosting are eliminated, and an imaging quality of the image sensor chip is improved.

### BRIEF DESCRIPTION OF THE DRAWINGS

FIG. 1 is a schematic structural diagram of an image sensor package according to the conventional technology;

FIG. 2 is a schematic structural diagram of an image sensor package according to a preferred embodiment of the present disclosure; and

FIGS. 3 to 9 are schematic diagrams of intermediate structures formed in a packaging process according to preferred embodiments of the present disclosure.

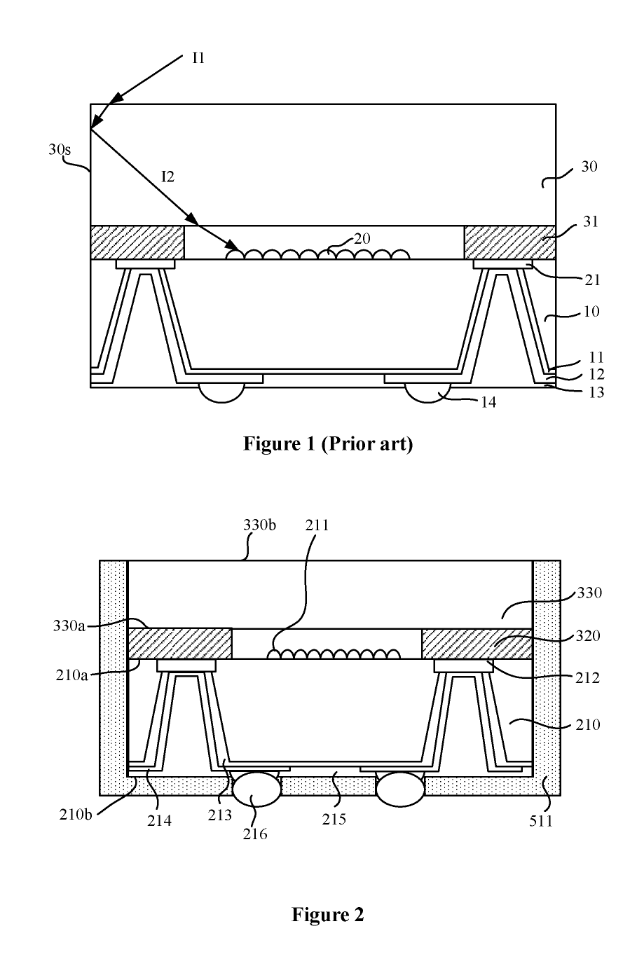

### DETAILED DESCRIPTION OF EMBODIMENTS

Specific embodiments of the present disclosure are described in detail in combination with the drawings as follows. The embodiments are not intended to limit the present disclosure, and any transformation in structure, method or functions made by those skilled in the art according to these embodiments fall within the protection scope of the present disclosure.

It should be noted that, these drawings are provided to assist understanding embodiments of the present disclosure rather than limit the present disclosure inappropriately. For clearness, dimensions shown in the drawings are not to scale, which may be zoomed in, zoomed out or changed. In addition, dimensions in three-dimensional space with length, width and depth should be included in practical manufacturing. The structure having a first feature “on” a second feature described as follows may include an embodiment in which the first feature contacts the second feature directly, and may also include an embodiment in which other features are formed between the first feature and the second feature, thus there may be no direct contact between the first feature and the second feature.

Reference is made to FIG. 2, which is a schematic structural diagram of an image sensor package according to a preferred embodiment of the present disclosure. The image sensor package includes: an image sensor chip 210 including a first surface 210a and a second surface 210b opposite to each other, where the first surface 210a is provided with a photosensitive region 211; a transparent substrate 330 including a first surface 330a and a second surface 330b opposite to each other, where the first surface 330a covers the first surface 210a; a supporting structure 320 provided on the first surface 330a, where the supporting structure 320 is located between the transparent substrate 330 and the image sensor chip 210, and the photosensitive region 211 is located in an accommodating cavity formed by surrounding by the supporting structure 320, the transparent substrate 330 and the image sensor chip 210.

A light absorption layer 511 is provided on sidewalls of the transparent substrate 330. The light absorption layer 511 can absorb light projected onto the sidewalls of the transparent substrate 330, thereby avoiding a case that total reflection of the light on the sidewalls of the transparent surface 330 interferes with the photosensitive region 211.

Further, the light absorption layer 511 covers outer sidewalls of the supporting structure 320, to improve an airtight performance of the image sensor package.

Contact pads 212 located at periphery of the photosensitive region 211 are provided on the first surface 210a of the image sensor chip 210. In this embodiment, the image sensor chip 210 is provided with: through holes located on the second surface 210b of the image sensor chip 210 and extending to the first surface 210a, where positions of the through holes correspond to positions of the contact pads 212, and the contact pads 212 are exposed through the through holes; an insulation layer 213 located on the second surface 210b of the image sensor chip 210 and in the through holes; a metal wiring layer 214 located in the through holes, where the metal wiring layer 214 is electrically connected to the contact pads 212 and extend to the second surface 210b of the image sensor chip 210; a solder mask 215 located on the second surface 210b of the image sensor chip 210, where the solder mask 215 is provided with openings and the metal wiring layer 214 is exposed through bottom of the openings; and solder bumps 216 located in the openings, where the solder bumps are electrically connected to the metal wiring layer 214. Therefore, the contact pads 212 are electrically connected to the solder bumps 216 through the metal wiring layer 214, and are electrically connected to external circuits through the solder bumps 216, to realize electrical connection between the image sensor chip 210 and the external circuits.

Further, the light absorption layer 511 covers sidewalls and the second surface 210b of the image sensor chip 210, and the solder bumps 216 are exposed through the light absorption layer 511, thereby further improving the airtight performance of the image sensor package.

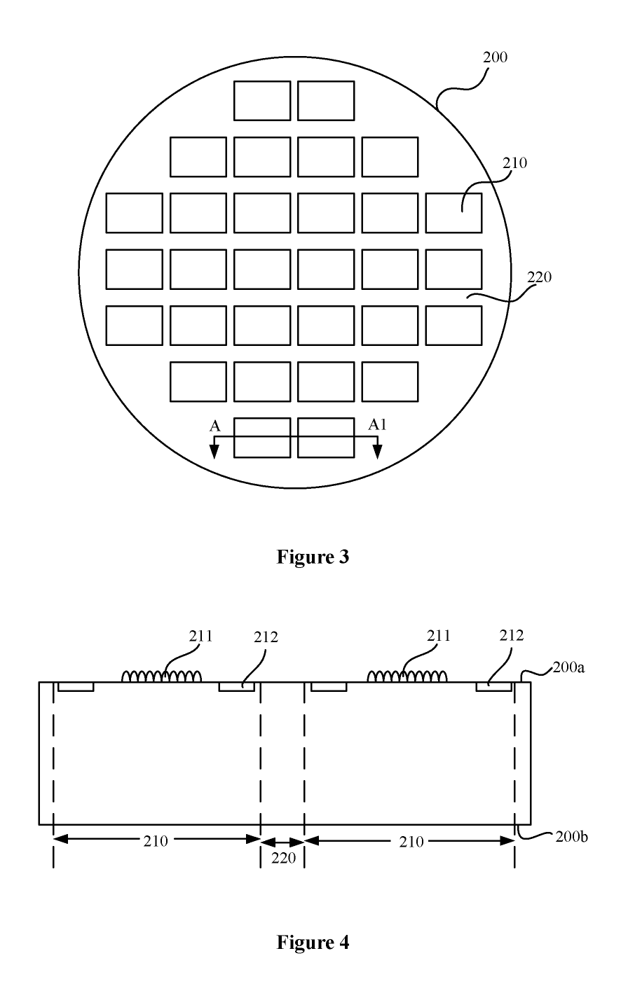

Correspondingly, a method of packaging an image sensor is provided according to embodiments of the present disclosure, to form the image sensor package shown in FIG. 2. Reference is made to FIGS. 3 to 9, which are schematic diagrams of intermediate structures formed in a packaging process according to preferred embodiments of the present disclosure.

Firstly, referring to FIGS. 3-4, a wafer 200 is provided. FIG. 3 is a top view structural diagram of the wafer 200, and FIG. 4 is a sectional view of the FIG. 3 along a line A-A1.

The wafer 200 includes a first surface 200a and a second surface 200b opposite to each other. The wafer 200 is provided with multiple image sensor chips 210 arranged in an array and cutting channel regions 220 located between adjacent image sensor chips 210. Cutting is performed along the cutting channel region 220 when packaging of the wafer 200 is completed, and multiple image sensor packages are formed.

The image sensor chip 210 is provided with a photosensitive region 211 and contact pads 212 located at periphery of the photosensitive region 211. The photosensitive region 211 may include multiple photodiodes arranged in an array which are configured to convert an optical signal illuminating the photosensitive region 211 into an electrical signal. The contact pad 212 functions as an input/output terminal via which devices in the photosensitive region 211 are connected to external circuits. The image sensor chip 210 may further include other functional devices, which is not limited by the present disclosure. Any semiconductor chips having a photo-sensing function may be regarded as the image sensor chip described in the present disclosure.

It should be noted that, in subsequent steps of the packaging method according to embodiments of the present disclosure, descriptions are made merely by taking the sectional view along the A-A1 direction of the wafer 200 shown in FIG. 3 as an example for simplicity, and similar process steps are executed simultaneously in other regions.

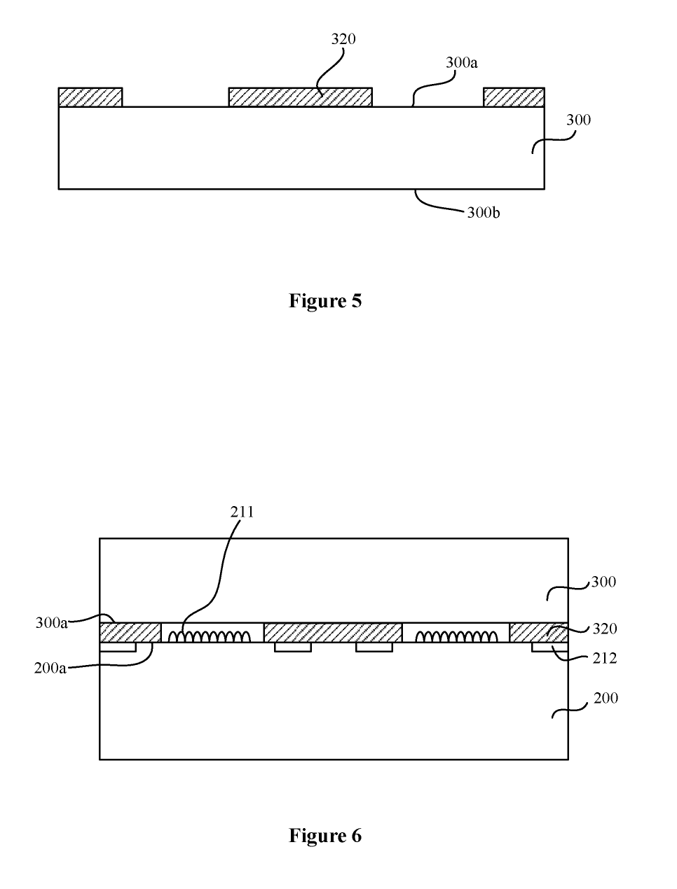

Next, referring to FIG. 5, a transparent cover plate 300 is provided. The transparent cover plate 300 covers the first surface 200a of the wafer 200 in subsequent processes, to protect the photosensitive region 211 on the wafer 200.

Since light needs to reach the photosensitive region 211 through the transparent cover plate 300, a transparent material with high transparency is applied in the transparent cover plate 300. Specifically, the transparent cover plate 300 may be made of inorganic glass, organic glass or other transparent materials having a specific intensity.

To guarantee the intensity and transparency of the transparent cover plate 300, a thickness of the substrate is selected according to specific requirements. In this embodiment, the transparent cover plate 300 has a thickness ranging from 50 μm to 500 μm, for example 400 μm.

The transparent cover plate 300 includes a first surface 300a and a second surface 300b opposite to each other. Both of the two surfaces 300a and 300b of the transparent cover plate 300 are flat and smooth, therefore scattering and diffusion reflection of incidence light may not occur. The transparent cover plate 300 is retained as the transparent substrate 330 of the image sensor chip 210 after the packaging and cutting are completed subsequently.

A supporting structure 320 is formed on the first surface 300a of the transparent cover plate 300. Multiple cavities arranged in an array are formed by the supporting structure 320 and the first surface 300a of the transparent cover plate 300. Each of the cavities corresponds to one photosensitive region 211.

In this embodiment, the supporting structure 320 is made of a photoresist. A photoresist coating is formed on the first surface 300a of the transparent cover plate 300 through a spraying process or a spin-coating process or the like. Patterning is performed on the photoresist coating through an exposing and developing process to form the supporting structure 320. In other embodiment, the supporting structure 320 may also be made of silicon oxide, silicon nitride, silicon oxynitride and other insulating dielectric materials formed by a deposition process. Patterning is performed by using photoetching and etching processes subsequently, to form the supporting structure 320.

Next, referring to FIG. 6, the first surface 300a of the transparent cover plate 300 is laminated with the first surface 200a of the wafer 200. The cavity formed by the supporting structure 320 covers the first surface 200a of the wafer 200 to form an accommodating cavity (not shown). The photosensitive region 211 is located in the accommodating cavity.

In this embodiment, the transparent cover plate 300 and the wafer 200 are laminated through an adhesive layer (not shown). For example, the adhesive layer may be formed on a top surface of the supporting structure 320 through a silk-screen printing process or a spin-coating process, and the first surface 300a of the transparent cover plate 300 and the first surface 200a of the wafer 200 are laminated through the adhesive layer. The adhesive layer has not only a function of bonding, but also functions of insulation and sealing. The adhesive layer may be made of polymer bonding materials, such as silica gel, epoxy resin, benzocyclobutene and the like.

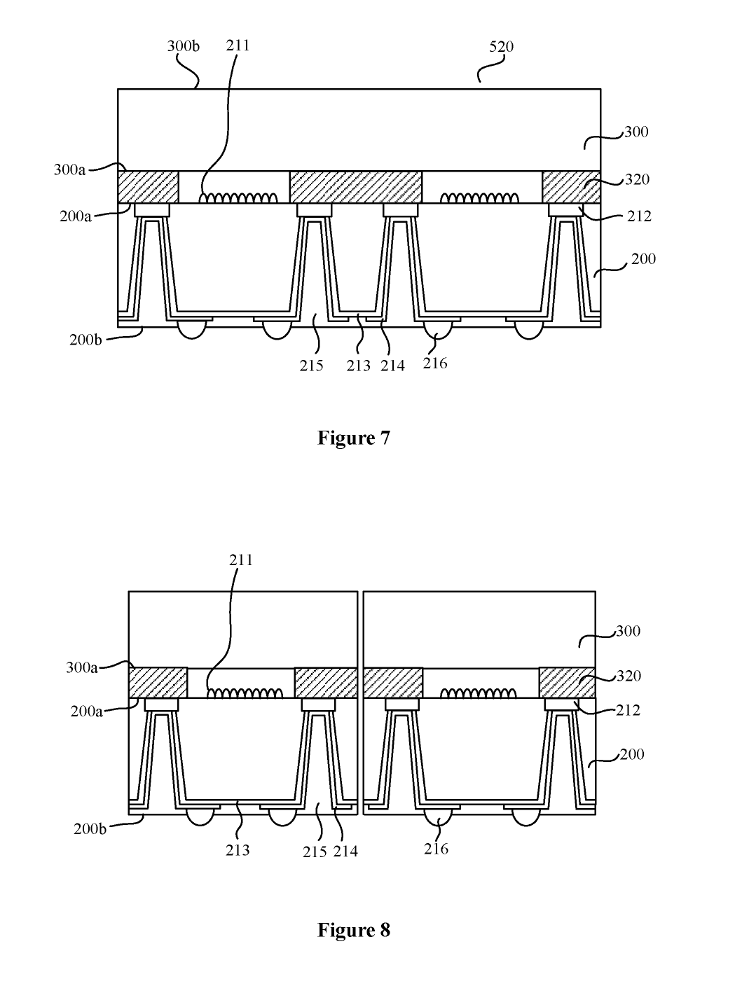

Next, referring to FIG. 7, packaging is performed on the wafer 200.

Firstly, thinning is performed on the wafer 200 from the second surface 200b of the wafer 200 for facilitating etching a through hole subsequently. The thinning of the wafer 200 may be performed by a mechanical grinding process or a chemical mechanical grinding process or the like.

The wafer 200 is etched from the second surface 200b of the wafer 200 to form through holes (not shown), and the contact pads 212 are exposed through the through holes.

An insulation layer 213 is formed on the second surface 200b of the wafer 200 and in the through holes. The insulation layer 213 may provide electrical insulation for the second surface 200b of the wafer 200, and may also provide electrical insulation for a substrate of the wafer 200 exposed through the through holes. The insulation layer 213 may be made of silicon oxide, silicon nitride, silicon oxynitride or insulating organic resin. A laser process, an exposing and developing process or an etching process is selected according to the material of the insulation layer 213 to expose the contact pads 212 through the insulation layer 213.

Next, a metal wiring layer 214 electrically connected to the contact pads 212 is formed on the second surface 200b of the wafer 200 and in the through holes. The metal wiring layer 214 extends to the second surface 200b of the wafer 200, and is formed through metal film deposition and etching of the metal film, for example the RDL process.

A solder mask 215 having openings (not shown) is formed on the second surface of the wafer 200. A part of a surface of the metal wiring layer 214 is exposed through the openings, and the solder mask 215 may be made of an insulation glue with photosensitivity.

Next, solder bumps 216 are formed on a surface of the solder mask 215. The solder bumps 216 are located in the openings and are electrically connected to the metal wiring layer 214. The solder bump 216 may be a solder ball, a metal column and other connection structures. The solder bump 216 may be made of copper, aluminium, gold, tin, lead or other metal materials.

Referring to FIG. 8, a wafer level image sensor package is cut into multiple packages by a cutting process, and each of the packages is provided with one image sensor chip 210 and one transparent substrate 330.

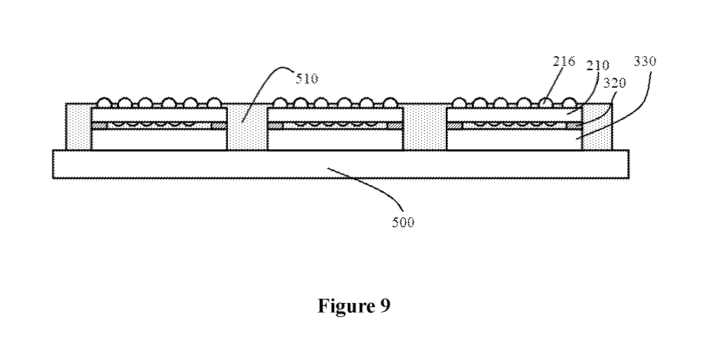

Reference is made to FIG. 9, which is a schematic diagram of forming a light absorption layer 511. Multiple packages are fixed on a substrate holder 500. The second surface 320b of the transparent substrate 330 is arranged on the substrate holder 500. The second surface 320b of the transparent substrate 330 fits closely on the substrate holder 500, to prevent the second surface 320b of the transparent substrate 330 from being polluted by a light absorption material during the subsequent injection molding process.

The package is surrounded by the light absorption material 510 by means of the injection molding process. A surrounding degree of the package by the light absorption material is controlled by adjusting the method of the injection molding process and the amount of injection molding and so on, such that merely sidewalls of the transparent substrate 330 are surrounded by the light absorption material 510, and further outer sidewalls of the supporting structure 320 are surrounded by the light absorption material 510. In this embodiment, the light absorption material 510 clads the sidewalls of the transparent substrate 330, the outer sidewalls of the supporting structure 320, sidewalls of the image sensor chip 210 and the second surface of the image sensor chip 210, and exposes the solder bumps 216, thereby facilitating the subsequent electrical connection of the solder bumps 216 with other circuits.

After the light absorption material 510 is solidified and shaped, packages are separated from each other by the cutting process to form the light absorption layer 511 on the package, thereby forming the image sensor package as shown in FIG. 2.

The light absorption layer 511 is made of an opaque black organic material or a black organic material with low transparency, that is, vinyl. The vinyl is black epoxy resin usually used in the semiconductor process. Some vinyl has photosensitivity.

When the vinyl has photosensitivity, the light absorption material 510 may be used to cover the solder bumps 216 during performing of the injection molding process, and the solder bumps 216 are exposed through the exposing and developing process. The cutting process is performed to separate the packages connected through the light absorption material 510.

It should be understood that, the present specification is described according to embodiments just for clarity, but each embodiment does not merely include one independent technical solution. Those skilled in the art should take the specification as a whole, in which technical solutions in embodiments may be combined suitably to form other embodiments understandable for those skilled in the art.

The detailed description above is only for feasible embodiments of the present disclosure and is not intended to limit the protection scope of the present disclosure. Any equivalent implementations or changes made without departing from the technology and spirit of the present disclosure should be included in the protection scope of the present disclosure.

1. An image sensor package, comprising:
an image sensor chip comprising a first surface and a second surface opposite to each other, wherein the first surface is provided with a photosensitive region;
a transparent substrate comprising a first surface and a second surface opposite to each other, wherein the first surface of the transparent substrate covers the first surface of the image sensor chip; and
a light absorption layer, wherein the light absorption layer covers sidewalls of the transparent substrate.

2. The image sensor package according to claim 1, wherein a supporting structure is arranged between the transparent substrate and the image sensor chip to form a gap between the transparent substrate and the image sensor chip; an accommodating cavity is formed by surrounding by the supporting structure, the transparent substrate and the image sensor chip; the photosensitive region is located in the accommodating cavity; and the light absorption layer covers outer sidewalls of the supporting structure.

3. The image sensor package according to claim 2, wherein
the first surface of the image sensor chip is provided with contact pads, and the contact pads are located at periphery of the photosensitive region;
the second surface of the image sensor chip is provided with through holes through which the contact pads are exposed;
a metal wiring layer electrically connected to the contact pads is arranged in the through holes, and the metal wiring layer extends to the second surface of the image sensor chip; and
solder bumps electrically connected to the metal wiring layer are provided on the second surface of the image sensor chip, the light absorption layer covers sidewalls and the second surface of the image sensor chip, and the solder bumps are exposed through the light absorption layer.

4. The image sensor package according to claim 1, wherein the light absorption layer is made of vinyl.

5. A method of packaging an image sensor, comprising:
providing a wafer comprising a first surface and a second surface opposite to each other, wherein the wafer is provided with a plurality of image sensor chips arranged in an array, each of the image sensor chips is provided with a photosensitive region, and the photosensitive region is located on the first surface;
providing a transparent cover plate comprising a first surface and a second surface opposite to each other, wherein the transparent cover plate comprises a plurality of transparent substrates, and each of the transparent substrates corresponds to one of the image sensor chips;
laminating the wafer with the transparent cover plate, wherein the first surface of the transparent cover plate covers the first surface of the wafer;
cutting a wafer level image sensor package into a plurality of packages by a cutting process, wherein each of the packages is provided with one of the image sensor chips and one of the transparent substrates; and
forming a light absorption layer on sidewalls of the transparent substrate.

6. The method of packaging the image sensor according to claim 5, wherein the forming the light absorption layer comprises:
providing a substrate holder;
fixing the plurality of packages on the substrate holder, wherein the second surface of the transparent substrate is arranged on the substrate holder; and
performing injection molding on the plurality of packages by an injection molding process to form the light absorption layer.

7. The method of packaging the image sensor according to claim 5, wherein before the laminating the wafer with the transparent cover plate, the method further comprises:
forming a supporting structure on the first surface of the transparent cover plate; and
forming a plurality of accommodating cavities by surrounding by the supporting structure, the transparent cover plate and the wafer, wherein each of the accommodating cavities corresponds to one of the image sensor chips, the photosensitive region is located in the accommodating cavity, and the light absorption layer covers outer sidewalls of the supporting structure.

8. The method of packaging the image sensor according to claim 7, wherein
the first surface of the image sensor chip is further provided with contact pads, and the contact pads are located at periphery of the photosensitive region;
the second surface of the image sensor chip is provided with through holes through which the contact pads are exposed;
the through holes are provided with a metal wiring layer electrically connected to the contact pads, and the metal wiring layer extends to the second surface of the image sensor chip; and
the second surface of the image sensor chip is provided with solder bumps electrically connected to the metal wiring layer, the light absorption layer covers sidewalls and the second surface of the image sensor chip, and the solder bumps are exposed through the light absorption layer.

9. The method of packaging the image sensor according to claim 5, wherein the light absorption layer is made of vinyl.
